(19) United States
(12) Patent Application Publication
(10) Pub. No.: US 2019/0123229 A1
(43) Pub. Date: Apr. 25, 2019

(54) SOLAR CELL MODULE

(71) Applicant: KYOCERA CORPORATION, Kyoto (JP)

(72) Inventor: Mitsuo Yamashita, Higashiomi-shi (JP)

(21) Appl. No.: 16/228,334

(22) Filed: Dec. 20, 2018

Related U.S. Application Data
(63) Continuation of application No. PCT/JP2017/022490, filed on Jun. 19, 2017.

(30) Foreign Application Priority Data
Jun. 28, 2016 (JP) 2016-128064

(51) Int. Cl. H01L 31/05

(52) U.S. Cl. CPC H01L 31/0508; H01L 31/0512

(57) ABSTRACT

A solar cell module includes solar cell elements arranged along a first direction and a wiring material. The solar cell elements include a first solar cell element having first and second surfaces, and a second solar cell element having third and fourth surfaces. A first region along an end surface of the first solar cell element located on the first surface and a second region along an end surface of the second solar cell element located on the fourth surface overlap with each other with the wiring material interposed in between. The wiring material includes first to third portions sequentially located along a longitudinal direction thereof. The first portion is joined to the first surface. The third portion is joined to the fourth surface. The second portion includes a non-joined portion located between the first and second region. The non-joined portion is extending along a direction intersecting the first direction.

### CROSS-REFERENCE TO RELATED APPLICATIONS

The present application is a continuation based on PCT Application No. PCT/JP2017/022490 filed on Jun. 19, 2017, which claims the benefit of Japanese Application No. 2016-128064, filed on Jun. 28, 2016. PCT Application No. PCT/JP2017/022490 is entitled “SOLAR CELL MODULE”, and Japanese Application No. 2016-128064 is entitled “SOLAR CELL MODULE”. The contents of which are incorporated by reference herein in their entirety.

### FIELD

Embodiments of the present disclosure relate generally to solar cell modules.

### BACKGROUND

A solar cell module generally has a structure in which a solar cell string including a plurality of solar cell elements connected in series is interposed between a light transmissive substrate and a rear-surface sheet, together with a filler.

In the solar cell string, for example, when adjacent solar cell elements arranged with a gap are connected to each other by a connection conductor or the like, the gap becomes a region that does not contribute to power generation. Therefore, the presence of the gap reduces a ratio of an area occupied by a region contributing to power generation on a light receiving surface of the solar cell module. This reduces conversion efficiency indicating a ratio of energy to be converted into electric energy, to optical energy of light incident on the solar cell module.

Accordingly, a solar cell module has been proposed in which an electrode on a front surface in a first solar cell element and an electrode on a rear surface in a second solar cell element are connected by a joining material such as solder, at a portion where adjacent solar cell elements partially overlap with each other.

### SUMMARY

A solar cell module is disclosed. In one embodiment, a solar cell module includes a plurality of solar cell elements and one or more first wiring materials. The plurality of solar cell elements include: a first solar cell element having a first surface and a second surface opposite the first surface; and a second solar cell element having a third surface and a fourth surface opposite the third surface, and the plurality of solar cell elements are arranged along a first direction. The one or more first wiring materials are located in a state of electrically connecting the first surface and the fourth surface. The first solar cell element has a first end surface adjacent to the second solar cell element and facing the first direction in a state of connecting the first surface and the second surface. The second solar cell element has a second end surface adjacent to the first solar cell element and facing a second direction opposite to the first direction side, in a state of connecting the third surface and the fourth surface. A first region located along the first end surface on the first surface and a second region located along the second end surface on the fourth surface are located in a state of overlapping with each other with the one or more first wiring materials interposed in between. Each of the one or more first wiring materials includes a first portion, a second portion, and a third portion that are sequentially located along a longitudinal direction of a corresponding one of the one or more first wiring materials. The first portion is in a state of being joined to a third region different from the first region on the first surface. The third portion is in a state of being joined to a fourth region different from the second region on the fourth surface. The second portion includes a non joined portion located between the first region and the second region and located in a state of not being joined to any of the first region and the second region. The non joined portion is located in a state of extending along a direction intersecting the first direction.

### BRIEF DESCRIPTION OF DRAWINGS

FIG. 1 illustrates a plan view showing a configuration of an example of a solar cell module.

FIG. 2 illustrates a rear view showing a configuration of an example of the solar cell module.

FIG. 3 illustrates a cross-sectional view showing a cross section of the solar cell module taken along line III-III of FIG. 1.

FIG. 4 illustrates a plan view showing a configuration of an example of a solar cell element.

FIG. 5 illustrates a rear view showing a configuration of an example of the solar cell element.

FIG. 6 illustrates a cross-sectional view showing a cross section of the solar cell element taken along line VI-VI of FIG. 4.

FIG. 7 illustrates an exploded perspective view showing a part of a configuration of an example of a solar cell string.

FIG. 8 illustrates a plan view showing a part of a configuration of an example of the solar cell string.

FIG. 9 illustrates a rear view showing a part of a configuration of an example of the solar cell string.

FIG. 10 illustrates a plan view showing a configuration of an example of a wiring material.

FIG. 11 illustrates a cross-sectional view showing a cross section of the wiring material taken along line XI-XI in FIGS. 10, 26, and 27.

FIG. 12 illustrates a plan view showing an example of a state of the wiring material being deformed.

FIG. 13 illustrates a plan view showing an example of a state of the wiring material being deformed.

FIG. 14 illustrates a plan view showing a configuration of an example of the wiring material.

FIG. 15 illustrates a cross-sectional view showing a cross section of the wiring material taken along line XV-XV in FIGS. 14, 16, 28, and 29.

FIG. 16 illustrates a plan view showing a configuration of an example of the wiring material.

FIG. 17 illustrates a flowchart showing an example of a manufacturing flow of the solar cell module.

FIG. 18 illustrates a view showing a state in a process of manufacturing the solar cell module.

FIG. 19 illustrates a plan view showing a part of a configuration of an example of the solar cell string.

FIG. 20 illustrates a cross-sectional view showing a cross section of a part of the solar cell string taken along line XX-XX of FIG. 19.

FIG. 21 illustrates a plan view showing an example of a state of the wiring material being deformed.

FIG. 22 illustrates a plan view showing an example of a state of the wiring material being deformed.

FIG. 23 illustrates a rear view showing a part of a configuration of an example of the solar cell element.

FIG. 24 illustrates a plan view showing a part of a configuration of an example of the solar cell string.

FIG. 25 illustrates a rear view showing a part of a configuration of an example of the solar cell string.

FIG. 26 illustrates a plan view showing a configuration of an example of the wiring material.

FIG. 27 illustrates a plan view showing a configuration of an example of the wiring material.

FIG. 28 illustrates a plan view showing a configuration of an example of the wiring material.

FIG. 29 illustrates a plan view showing a configuration of an example of the wiring material.

FIG. 30 illustrates a plan view showing a configuration of an example of the solar cell element.

FIG. 31 illustrates a rear view showing a configuration of an example of the solar cell element.

FIG. 32 illustrates a plan view showing a part of a configuration of an example of the solar cell string.

FIG. 33 illustrates a rear view showing a part of a configuration of an example of the solar cell string.

### DETAILED DESCRIPTION

Regarding a solar cell module, for example, in order to improve conversion efficiency, it is conceivable to partially overlap adjacent solar cell elements. Such a configuration can be realized by electrically connecting an electrode on a front surface in a first solar cell element and an electrode on a rear surface in a second solar cell element with a joining material such as solder, at an overlapping portion where the first solar cell element and the second solar cell element overlap with each other.

However, in such a solar cell module, there is a possibility that expansion and contraction of a solar cell element and a filler occur in accordance with a temperature change due to sunlight irradiation, a change in atmospheric temperature, rainfall, snowfall, and the like, and concentration of a shear stress occurs in the joining material at the above-described overlapping portion. When the shear stress concentrates on the joining material, a crack may occur in the joining material and a semiconductor substrate of the solar cell element, and an electrode joined with the joining material may be separated from the semiconductor substrate. Therefore, there is room for improvement in enhancing reliability and an output of the solar cell module.

Further, for example, in the above-described overlapping portion, an electrode on the front surface in the first solar cell element and an electrode on the rear surface in the second solar cell element are connected by the joining material. Therefore, in a configuration in which a bus bar electrode and a finger electrode collect electricity on the front surface side of the first solar cell element, power collection is not sufficient. From this point of view as well, there is room for improvement in enhancing the output of the solar cell module.

Accordingly, the inventors of the present disclosure have created a technology that can enhance conversion efficiency and reliability in a solar cell module. Regarding this, each embodiment will be described with reference to the drawings below.

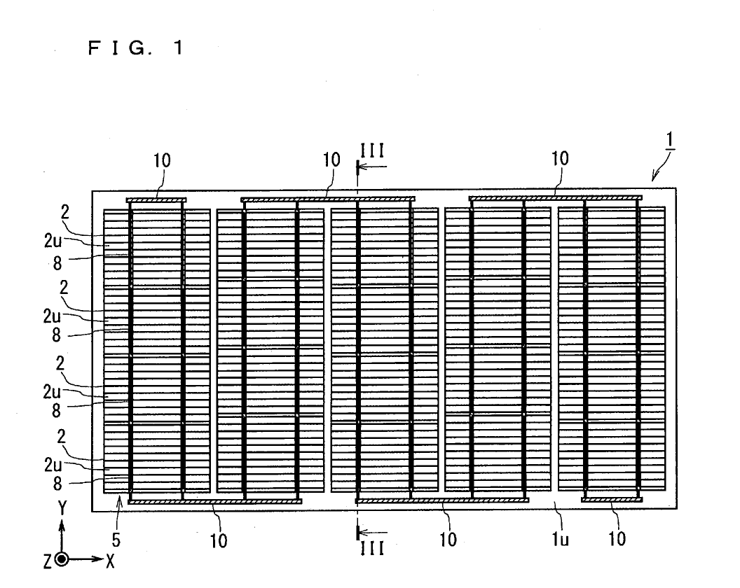

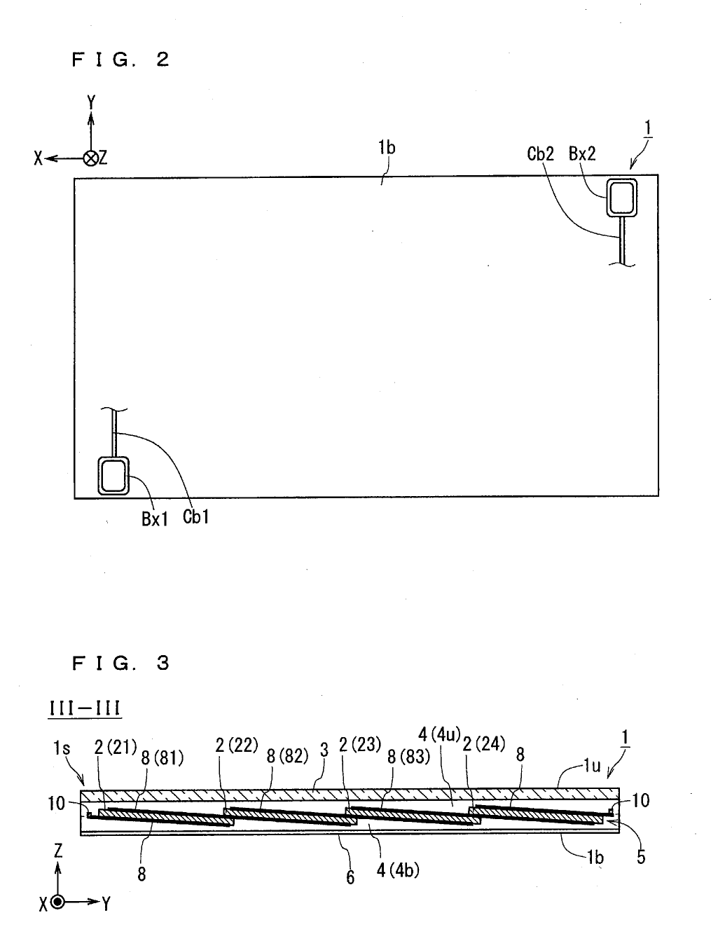

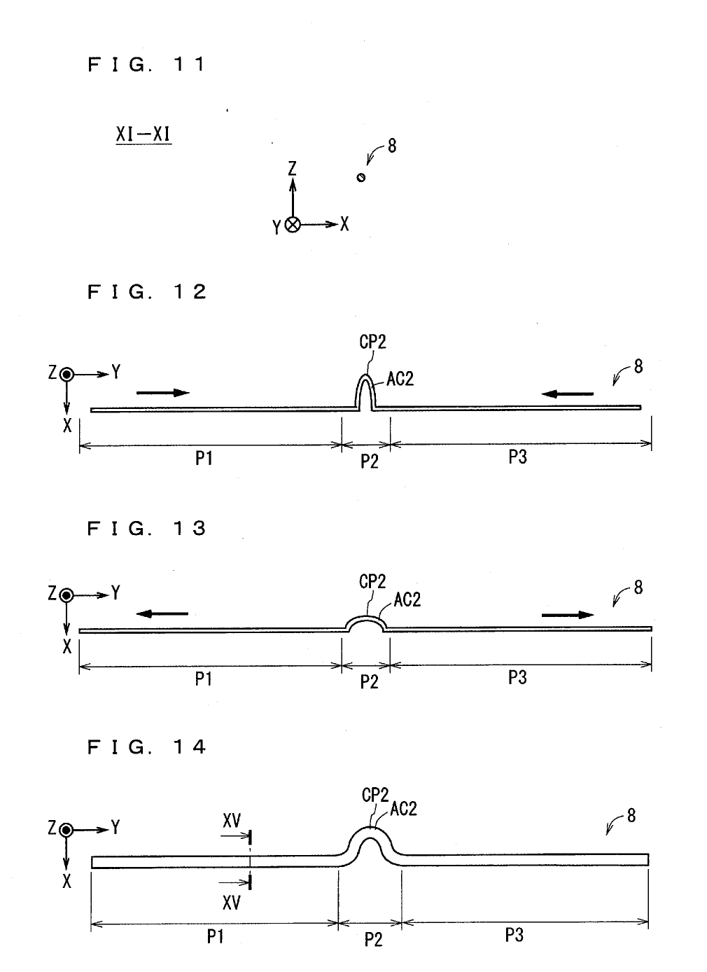

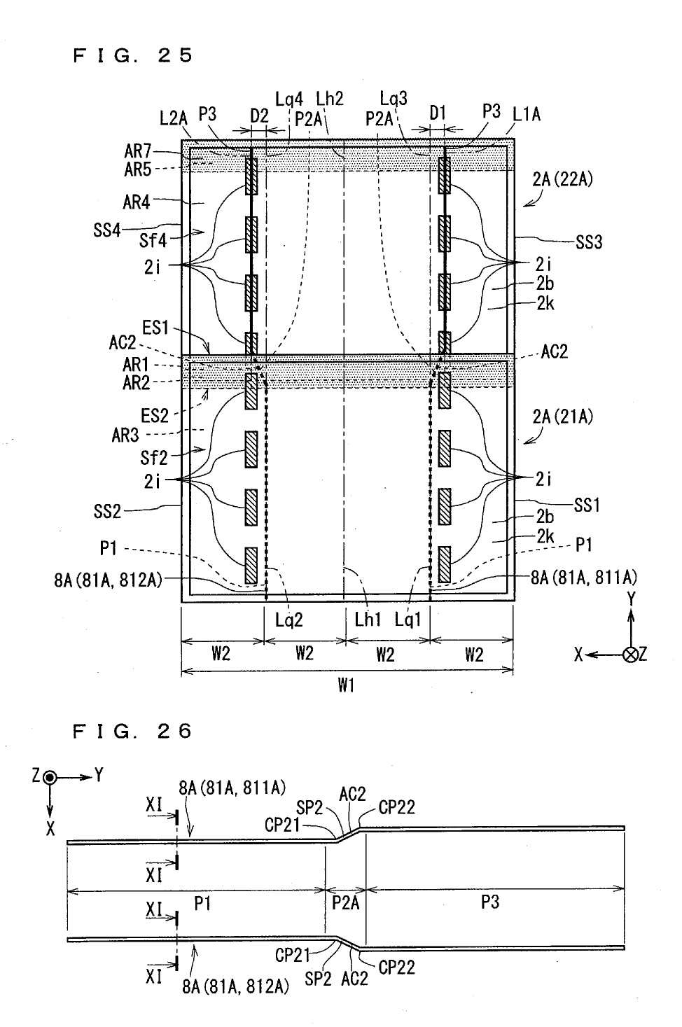

In the drawings, the same reference numerals are given to portions having similar configurations and functions, and redundant explanations are omitted in the following description. Further, the drawings are schematically shown. In FIGS. 1 to 16 and FIGS. 18 to 33, a right-handed XYZ coordinate system is given. In the XYZ coordinate system, a direction (also referred to as a first direction) in which a plurality of solar cell elements 2 are arranged in a solar cell string 5 is defined as a +Y direction, a direction in which a plurality of solar cell strings 5 are arranged is defined as a +X direction, and a direction orthogonal to both the +X direction and the +Y direction is defined as a +Z direction.

### 1. First Embodiment

<1-1. Solar Cell Module>

A solar cell module 1 according to a first embodiment will be described with reference to FIGS. 1 to 11.

As shown in FIGS. 1 to 3, the solar cell module 1 includes, for example, a light transmissive substrate 3; a sealing material 4; a plurality of (five, in this case) solar cell strings 5; a sheet member 6 as a rear surface protective member; and power supply boxes Bx1 and Bx2. The sealing material 4 includes, for example, a first sealing material (also referred to as a front-surface-side sealing material) 4u located on a front surface side of the solar cell module 1; and a second sealing material (also referred to as a rear-surface-side sealing material) 4b located on a rear surface side of the solar cell module 1.

In the example of FIG. 3, in the solar cell module 1, the light transmissive substrate 3, the front-surface-side sealing material 4u, the plurality of solar cell strings 5, the rear-surface-side sealing material 4b, and the sheet member 6 are located so as to be stacked in the −Z direction in the order described herein. Therefore, the solar cell module includes a stacked body is including the light transmissive substrate 3, the front-surface-side sealing material 4u, the solar cell string 5, the rear-surface-side sealing material 4b, and the sheet member 6. The power supply boxes Bx1 and Bx2 are located on a surface on the −Z side (also referred to as a rear surface) of the sheet member 6. The power supply boxes Bx1 and Bx2 are electrically connected to the plurality of solar cell strings 5. The power supply boxes Bx1 and Bx2 can output voltages and currents obtained by photoelectric conversion in the plurality of solar cell strings 5, with cables Cb1 and Cb2.

In the solar cell module 1, an annular frame body may be or may not be located along an outer periphery of the stacked body 1s. Here, if the solar cell module 1 has a rectangular outer edge in plan view of the solar cell module 1 from the +Z side, for example, an annular frame body having a rectangular inner edge and a rectangular outer edge can be adopted as the annular frame body, for example.

Next, each member in the solar cell module 1 will be described.

<1-1-1. Light Transmissive Substrate>

The light transmissive substrate 3 is, for example, a flat plate-shaped member. In the example of FIG. 1, in plan view of the light transmissive substrate 3 from the +Z side, the light transmissive substrate 3 has a rectangular outer edge. The light transmissive substrate 3 can protect the plurality of solar cell strings 5. A surface on the +Z side of the light transmissive substrate 3 forms a surface on the +Z side of the solar cell module 1, and can serve as a surface (also referred to as a light receiving surface) 1u that can receive light in the solar cell module 1. Here, since the light transmissive substrate 3 has a light transmitting property, light passes through the light transmissive substrate 3 and is incident on the plurality of solar cell strings 5. This can realize power generation through photoelectric conversion in the plurality of solar cell strings 5. If glass or resin such as acrylic or polycarbonate is adopted as a material of the light transmissive substrate 3, for example, a light transmissive substrate 3 having a light transmitting property can be realized. Here, as the glass, for example, a material with high light transmittance, such as white plate glass, tempered glass, heat ray reflecting glass and the like having a thickness of about 2 mm to 5 mm can be adopted.

<1-1-2. Sealing Material>

For example, the front-surface-side sealing material 4u and the rear-surface-side sealing material 4b can serve as a filler that holds the plurality of solar cell strings 5, and can serve as a sealing material that seals the plurality of solar cell strings 5. The front-surface-side sealing material 4u and the rear-surface-side sealing material 4b can be made of, for example, a thermosetting resin or the like. As the thermosetting resin, for example, one containing ethylene vinyl acetate copolymer (EVA) or polyvinyl butyral (PVB) as a main component is adopted. The thermosetting resin may contain a crosslinking agent.

<1-1-3. Solar Cell String>

Each solar cell string 5 includes, for example, the plurality (four, in this case) of solar cell elements 2 arranged along a first direction (+Y direction, in this case), and a plurality of wiring materials 8.

<1-1-3-1. Solar Cell Element>

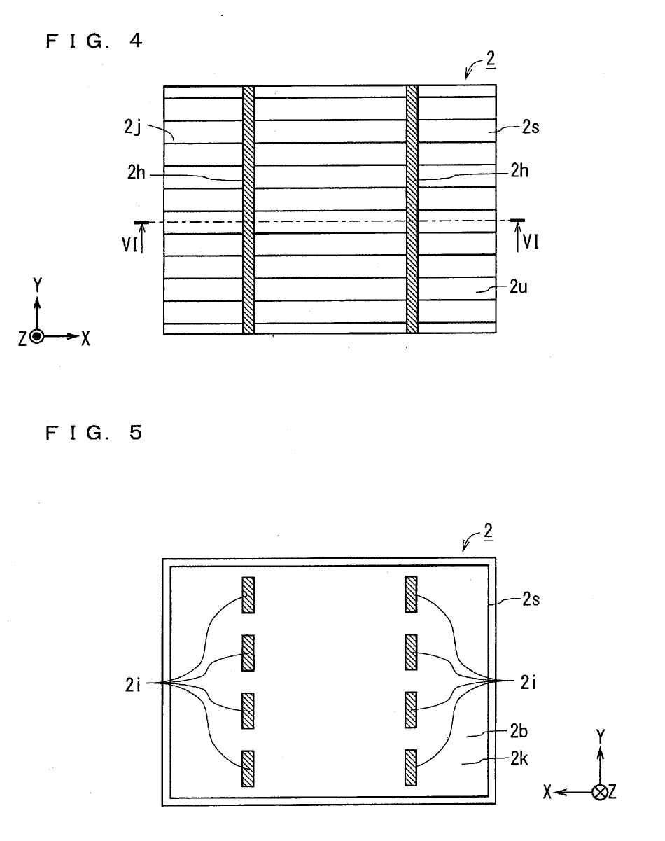

The solar cell element 2 can convert incident sunlight into electricity. As shown in FIGS. 4 and 5, the solar cell element 2 has a surface on the +Z side (also referred to as an element front surface) 2u and a surface on the −Z side (also referred to as an element rear surface) 2b located on a rear side of the element front surface 2u. Here, for example, the light receiving surface 1u of the solar cell module 1 where light is mainly incident is located on the element front surface 2u side of the solar cell element 2. Further, for example, a non-light receiving surface 1b of the solar cell module 1 where light is not mainly incident is located on the element rear surface 2b side of the solar cell element 2.

In the examples of FIGS. 4 to 6, in each solar cell element 2, each of the element front surface 2u and the element rear surface 2b has a rectangular outer shape. Specifically, in plan view of the solar cell element 2 from the element front surface 2u side, the outer shape of the solar cell element 2 is, for example, a rectangular shape having four sides including a pair of two sides along the +X direction and a pair of two sides along the +Y direction.

Each solar cell element 2 includes, for example, a semiconductor substrate 2s, an insulation layer 2g, a front-surface-side bus bar electrode 2h, a finger electrode 2j, an extraction electrode (also referred to as a rear-surface-side bus bar electrode) 2i, and a collector electrode 2k.

For the semiconductor substrate 2s, for example, it is possible to apply a crystalline semiconductor such as crystalline silicon, an amorphous semiconductor such as amorphous silicon, a compound semiconductor using four kinds of elements of copper, indium, gallium, and selenium, a compound semiconductor using cadmium telluride (CdTe), or the like. Here, for example, if the semiconductor substrate 2s is polycrystalline silicon, one side of the solar cell element 2 can be set to about 100 mm to 200 mm.

The semiconductor substrate 2s has, for example, a first conductivity type region 2o having a first conductivity type, a second conductivity type layer 2r, and a BSF region 2l.

The first conductivity type region 2o exhibits the first conductivity type by containing a preset dopant element (impurities for conductivity type control).

The second conductivity type layer 2r is, for example, located on the element front surface 2u side of the semiconductor substrate 2s. This second conductivity type layer 2r has, for example, a second conductivity type opposite to the first conductivity type of the semiconductor substrate 2s. Here, for example, there can be considered a case where the first conductivity type is p-type and the second conductivity type is n-type, and a case where the first conductivity type is n-type and the second conductivity type is p-type. Then, between a region of the first conductivity type and a region of the second conductivity type, a pn junction region is formed. Here, for example, if the semiconductor substrate 2s is a crystalline silicon substrate having p-type conductivity, for example, the second conductivity type layer 2r can be formed by diffusing impurities such as phosphorus on a surface (also referred to as a substrate front surface) 2s1, on the element front surface 2u side in the crystalline silicon substrate.

The BSF region 2l is located, for example, on the element rear surface 2b side of the semiconductor substrate 2s. This BSF region 2l has, for example, a first conductivity type similar to that of the semiconductor substrate 2s. Here, for example, the BSF region 2l is located in which a concentration of a dopant element is higher than that of the original semiconductor substrate 2s, in a surface layer portion of the element rear surface 2b side of the semiconductor substrate 2s. Therefore, for example, if the first conductivity type is p-type, the BSF region 2l contains more p-type carriers. For example, the BSF region 2l can form an internal electric field on a surface (also referred to as a substrate rear surface) 2s2 side on the element rear surface 2b side in the semiconductor substrate 2s. Therefore, the BSF region 2l has a function of reducing an occurrence of recombination of carriers in a region near the substrate rear surface 2s2 in the semiconductor substrate 2s, to reduce reduction of photoelectric conversion efficiency.

For example, the insulation layer 2g is located in a region where the front-surface-side bus bar electrode 2h and the finger electrode 2j are not formed, on the second conductivity type layer 2r. As a material of the insulation layer 2g, for example, silicon nitride, titanium oxide, silicon oxide, or the like can be adopted. The insulation layer 2g can be formed by, for example, a plasma enhanced chemical vapor deposition (PECVD) method, an evaporation method, a sputtering method, or the like.

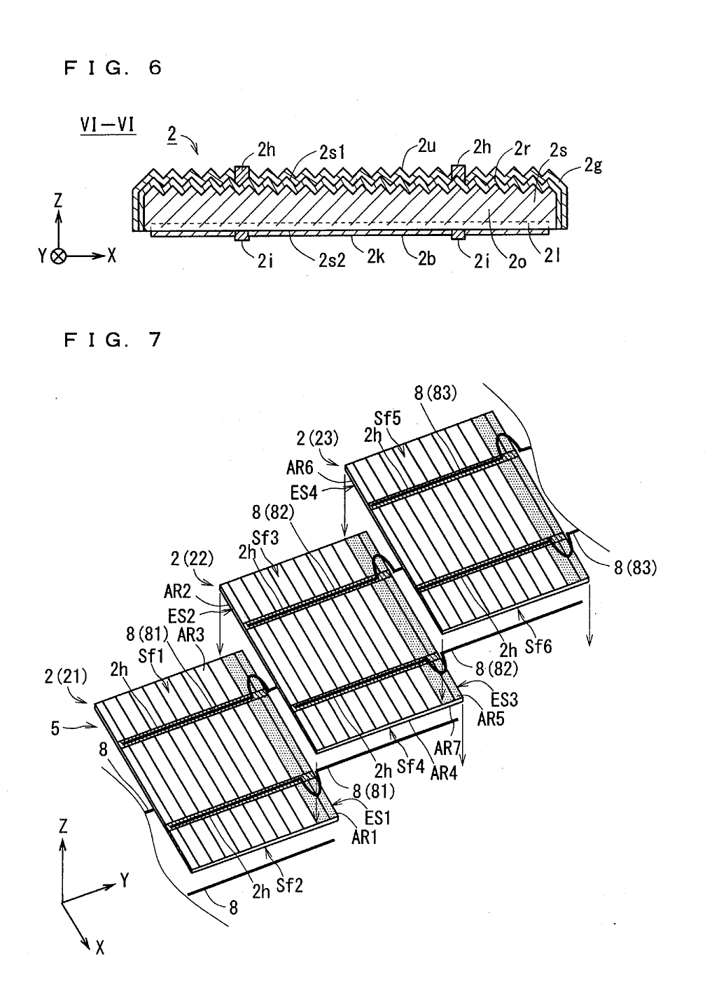

The front-surface-side bus bar electrode 2h and the finger electrode 2j are, for example, located on the substrate front surface 2s1 in the semiconductor substrate 2s. In the examples of FIGS. 4 and 6, two substantially parallel front-surface-side bus bar electrodes 2h are located on the substrate front surface 2s1, and a large number of substantially parallel finger electrodes 2j are located, for example, so as to be substantially orthogonal to the two front-surface-side bus bar electrodes 2h. The front-surface-side bus bar electrode 2h has a width of about 1.3 mm to 2.5 mm, for example. The finger electrode 2j has a width of about 50 μm to 200 μm, for example. That is, the width of the finger electrode 2j is smaller than the width of the front-surface-side bus bar electrode 2h. Further, a plurality of finger electrodes 2j are located with an interval of about 1.5 mm to 3 mm from each other. Thicknesses of these front-surface-side bus bar electrodes 2h and finger electrodes 2j can be set to about 10 μm to 40 μm. The front-surface-side bus bar electrode 2h and the finger electrode 2j can be formed by, for example, applying a conductive paste containing mainly silver in a desired shape with screen printing or the like and then baking.

The rear-surface-side bus bar electrode 2i and the collector electrode 2k are, for example, located on the substrate rear surface 2s2 in the semiconductor substrate 2s. In the examples of FIGS. 5 and 6, in the solar cell element 2, two rows of substantially parallel rear-surface-side bus bar electrodes 2i are located on the substrate rear surface 2s2. Further, the collector electrode 2k is located substantially on an entire surface of a region where the rear-surface-side bus bar electrode 2i is not located, on the substrate rear surface 2s2. Here, each of the two rows of rear-surface-side bus bar electrodes 2i may be, for example, an integral linear electrode, or may be formed of a plurality of (four, in this case) electrodes arranged in one line. Further, for example, each of the two rows of the rear-surface-side bus bar electrodes 2i is located on an opposite side of the front-surface-side bus bar electrode 2h with the semiconductor substrate 2s interposed in between. The rear-surface-side bus bar electrode 2i has a thickness of, for example, about 10 μm to 30 μm and has a width of about 1.3 mm to 7 mm. The rear-surface-side bus bar electrode 2i can be formed by the same material and manufacturing method as the above-described front-surface-side bus bar electrode 2h. The collector electrode 2k has a thickness of, for example, about 15 μm to 50 μm. The collector electrode 2k can be formed, for example, by applying an aluminum paste as a conductive paste mainly containing aluminum in a desired shape and then baking.

<1-1-3-2. Wiring Material>

As shown in FIGS. 1 and 3, the wiring material 8 electrically connects the element front surface 2u of one solar cell element 2 and the element rear surface 2b of the other solar cell element 2 among adjacent solar cell elements 2.

In the example of FIG. 3, in each solar cell string 5, a plurality of solar cell elements 2 are sequentially arranged. Specifically, the plurality of solar cell elements 2 include first one to fourth one of solar cell elements 21, 22, 23, and 24 as four solar cell elements 2. Further, each solar cell string 5 includes first to third pairs of wiring materials 81, 82, and 83 as three pairs of wiring materials 8 that can electrically connect adjacent solar cell elements 2.

The element front surface 2u of the first one of solar cell elements (also referred to as a first solar cell element) 2l and the element rear surface 2b of the second one of solar cell elements (also referred to as a second solar cell element) 22 are electrically connected by the first pair of wiring materials (also referred to as a first wiring material) 81 for connection. The element front surface 2u of the second solar cell element 22 and the element rear surface 2b of the third one of solar cell elements (also referred to as a third solar cell element) 23 are electrically connected by the second pair of wiring materials (also referred to as a second wiring material) 82 for connection. The element front surface 2u of the third solar cell element 23 and the element rear surface 2b of the fourth one of solar cell elements (also referred to as a fourth solar cell element) 24 are electrically connected by the third pair of wiring materials (also referred to as a third wiring material) 83 for connection. This allows, for example, the four solar cell elements 2 included in each solar cell string 5 to be electrically connected in series.

As a shape of the wiring material 8, for example, a linear shape or a belt shape can be adopted. As a material of the wiring material 8, for example, a conductive metal or the like can be adopted. Here, as the wiring material 8, for example, it is possible to adopt a copper wire material having a diameter of about 0.5 mm to 1 mm with an entire surface coated with solder.

The wiring material 8 is electrically connected to each of the front-surface-side bus bar electrode 2h and the rear-surface-side bus bar electrode 2i, for example, by joining by soldering. Further, in the example of FIG. 1, adjacent solar cell strings 5 in a direction (+X direction, in this case) intersecting the first direction (+Y direction, in this case) are electrically connected by a connecting member 10. For example, the connecting member 10 can be made of the same material as the wiring material 8.

<1-1-3-3. Connection Form between Adjacent Solar Cell Elements>

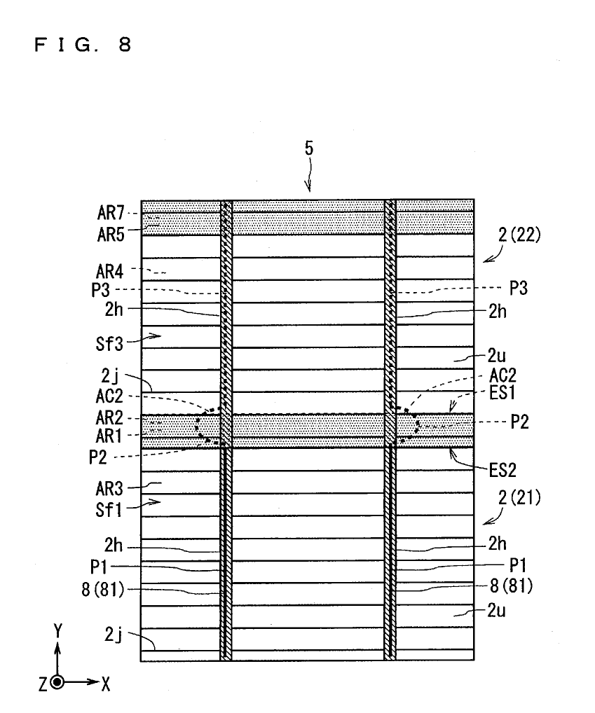

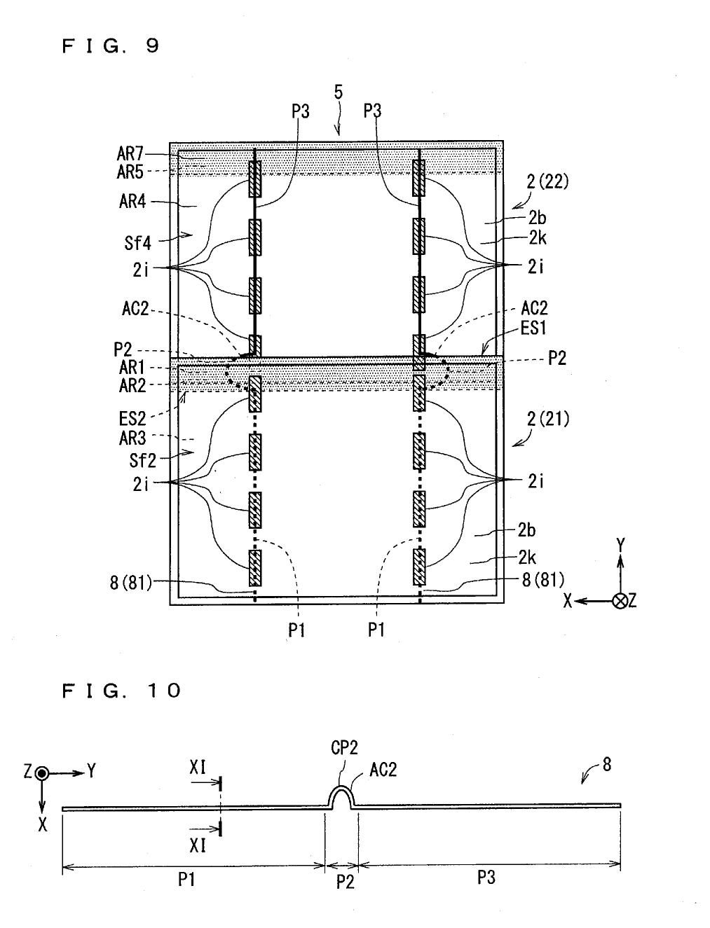

Here, an electrical connection form between the solar cell elements 2 adjacent to each other in the solar cell string 5 according to the first embodiment will be described with reference to FIGS. 1, 3, and 7 to 11. FIG. 7 illustrates an electrical connection form of three mutually adjacent solar cell elements 2 included in the solar cell string 5. FIGS. 8 and 9 illustrate an electrical connection form of two mutually adjacent solar cell elements 2 included in the solar cell string 5.

As shown in FIGS. 1 and 3, in each solar cell string 5, adjacent solar cell elements 2 partially overlap with each other. For example, as shown in FIG. 3, a portion near an end portion on a −Y side in the second solar cell element 22 overlaps on a portion near an end portion on a +Y side in the first solar cell element 21. Further, for example, a portion near an end portion on a −Y side in the third solar cell element 23 overlaps on a portion near an end portion on the +Y side in the second solar cell element 22. Further, for example, a portion near an end portion on a −Y side in the fourth solar cell element 24 overlaps on a portion near an end portion on the +Y side in the third solar cell element 23. In other words, the second solar cell element 22 is located at a position shifted from the first solar cell element 21 in the first direction (+Y direction, in this case), while the third solar cell element 23 is located at a position shifted from the second solar cell element 22 in the first direction (+Y direction, in this case). This can increase, in the solar cell module 1, a ratio of an area occupied by a region (also referred to as power generation region) where power generation is effectively performed in the solar cell element 2 to an area of the entire region of the light receiving surface 1u.

In the examples of FIGS. 7 to 9, for example, the first solar cell element 21 includes a first surface Sf1, which is the element front surface 2u, and a second surface Sf2, which is the element rear surface 2b located on a rear side of the first surface Sf1. Further, for example, the second solar cell element 22 has a third surface Sf3, which is the element front surface 2u, and a fourth surface Sf4, which is the element rear surface 2b located on a rear side of the third surface Sf3. Then, for example, a pair of first wiring materials 81 electrically connect the first surface Sf1 of the first solar cell element 21 and the fourth surface Sf4 of the second solar cell element 22. Here, for example, each first wiring material 81 electrically connects the front-surface-side bus bar electrode 2h of the first surface Sf1 and the rear-surface-side bus bar electrode 2i of the fourth surface Sf4.

Further, for example, the first solar cell element 21 has an end surface (also referred to as a first end surface) ES1 adjacent to the second solar cell element 22 and facing the first direction (+Y direction, in this case) in, a state of connecting the first surface Sf1 and the second surface Sf2. In the first embodiment, the first solar cell element 21 has four end surfaces connecting the first surface Sf1 and the second surface Sf2. The four end surfaces include, for example, a pair of end surfaces located in a state of extending along the first direction (+Y direction, in this case), and a pair of end surfaces located in a state of extending along the +X direction orthogonal to the first direction. More specifically, in the first solar cell element 21, the four end surfaces include an end surface located in a state of extending along the +Y direction on the +X side, an end surface located in a state of extending along the +Y direction on the −X side, an end surface located in a state of extending along the +X direction on the +Y side, and an end surface located in a state of extending along the +X direction on the −Y side.

For example, the second solar cell element 22 has an end surface (also referred to as a second end surface) ES2 adjacent to the first solar cell element 21 and facing a second direction (−Y direction, in this case) opposite to the first direction (+Y direction, in this case) in a state of connecting the third surface Sf3 and the fourth surface Sf4. In the first embodiment, the second solar cell element 22 has four end surfaces connecting the third surface Sf3 and the fourth surface Sf4. The four end surfaces include, for example, a pair of end surfaces located in a state of extending along the first direction (+Y direction, in this case), and a pair of end surfaces located in a state of extending along the +X direction orthogonal to the first direction. More specifically, in the second solar cell element 22, the four end surfaces include an end surface located in a state of extending along the +Y direction on the +X side, an end surface located in a state of extending along the +Y direction on the −X side, an end surface located in a state of extending along the +X direction on the +Y side, and an end surface located in a state of extending along the +X direction on the −Y side.

Between the first solar cell element 21 and the second solar cell element 22, for example, a first region AR1 of the first solar cell element 21 and a second region AR2 of the second solar cell element 22 overlap with each other with a pair of first wiring materials 81 interposed in between. Here, the first region AR1 is located along the first end surface ES1 on the first surface Sf1. The second region AR2 is located along the second end surface ES2 on the fourth surface Sf4. In the first embodiment, the first region AR1 has a first width in the second direction (−Y direction) from the first end surface ES1, and is located in a state of extending along the first end surface ES1 from an end portion of the first surface Sf1 on the −X side to an end portion of the first surface Sf1 on the +X side. Further, the second region AR2 has a first width in the first direction (+Y direction) from the second end surface ES2, and is located in a state of extending along the second end surface ES2 from an end portion of the fourth surface Sf4 on the −X side to an end portion of the fourth surface Sf4 on the +X side. The first width can be set to, for example, about several mm to 20 mm.

Here, as shown in FIGS. 8 to 10, each first wiring material 81 includes a first portion P1, a second portion P2, and a third portion P3 that are sequentially located along a longitudinal direction of the first wiring material 81.

The first portion P1 is, for example, in a state of being joined to a region (also referred to as a third region) AR3 different from the first region AR1 on the first surface Sf1 of the first solar cell element 21. Specifically, for example, in a region where the second solar cell element 22 does not overlap in the first surface Sf1, the first wiring material 81 is electrically connected to the front-surface-side bus bar electrode 2h. In the first embodiment, for example, the third region AR3 can be set as a remaining region of the first surface Sf1 except for the first region AR1.

The third portion P3 is, for example, in a state of being joined to a region (also referred to as a fourth region) AR4 different from the second region AR2 on the fourth surface Sf4 of the second solar cell element 22. Specifically, for example, in a region where the first solar cell element 21 does not overlap in the fourth surface Sf4, the first wiring material 81 is electrically connected to the rear-surface-side bus bar electrode 2i. In the first embodiment, for example, the fourth region AR4 can be set as a remaining region of the fourth surface Sf4 except for the second region AR2.

In other words, for example, the first wiring material 81 is located in a state of being joined to a non-overlapping region of the first solar cell element 21 and the second solar cell element 22 that are adjacent to each other. Therefore, for example, the first wiring material 81 is located in a state of being joined on the front-surface-side bus bar electrode 2h of the first solar cell element 21 and the rear-surface-side bus bar electrode 2i of the second solar cell element 22. This increases, for example, a cross-sectional area of a conductor through which collected charges pass. This can facilitate extraction of charges in the first solar cell element 21 and the second solar cell element 22. As a result, for example, the output of the solar cell module 1 can be enhanced.

Then, the second portion P2 includes, for example, a non-joined portion AC2 located in a state not being joined to any of the first region AR1 and the second region AR2. Here, the non-joined portion AC2 is located, for example, between the first region AR1 and the second region AR2. Further, the non joined portion AC2 includes a curved portion CP2 curved on a plane parallel to the first surface Sf1 and the fourth surface Sf4, and is located so as to intersect the first direction (+Y direction, in this case).

Here, for example, it is assumed that the first solar cell element 21, the second solar cell element 22, the first wiring material 81, and the like are thermally expanded and thermally contracted in accordance with a change in temperature. In this case, for example, as shown in FIGS. 10, 12, and 13, the second portion P2 that is not joined to the first solar cell element 21 and the second solar cell element 22 in the first wiring material 81 can be deformed. Therefore, for example, even when the first solar cell element 21, the second solar cell element 22, the first wiring material 81, and the like are thermally expanded and thermally contracted in accordance with a change in temperature, concentration of shear stress is unlikely to occur at a portion where the first solar cell element 21 and the second solar cell element 22 are joined to the first wiring material 81. This makes it difficult to cause, for example, occurrence of a crack in the first wiring material 81, the first solar cell element 21, and the second solar cell element 22, and peeling of the front-surface-side bus bar electrode 2h and the rear-surface-side bus bar electrode 2i joined with the first wiring material 81, and the like.

Therefore, adopting the above configuration can improve conversion efficiency and reliability in the solar cell module 1. As the deformation of the second portion P2, elastic deformation is mainly assumed, but the deformation of the second portion P2 may also include plastic deformation.

In the examples of FIGS. 7 to 10, the non-joined portion AC2 includes the portion (also referred to as a curved portion) CP2 that is bent so as to curve. Adopting such a configuration makes it easier to, for example, deform the non-joined portion AC2 of the first wiring material 81 in accordance with thermal expansion and thermal contraction of the first solar cell element 21, the second solar cell element 22, the first wiring material 81, and the like in the first direction (+Y direction, in this case). Therefore, for example, concentration of shear stress is unlikely to occur in the first solar cell element 21, the second solar cell element 22, and the first wiring material 81. The curved portion CP2 may be a portion bent in a form other than a curve, for example, flection or the like.

Further, in the examples of FIGS. 7 to 10, the non-joined portion AC2 is located along the first surface Sf1 and the fourth surface Sf4. Adopting such a configuration makes it easy to reduce, for example, a thickness of the overlapping portion of the first solar cell element 21 and the second solar cell element 22. As a result, a thickness of the solar cell module 1 is unlikely to increase.

Further, in the examples of FIGS. 7 to 10, as shown in FIG. 11, the wiring material 8 has, for example, a circular cross section perpendicular to the longitudinal direction thereof. Adopting such a configuration allows, for example, the wiring material 8 having a circular cross section to deform along the first surface Sf1 and the fourth surface Sf4 of first solar cell element 21 and second solar cell element 22 that are adjacent to each other. Therefore, for example, concentration of shear stress is unlikely to occur at a portion where the first solar cell element 21 and the second solar cell element 22 are joined to the first wiring material 81. The circular cross section can include, for example, not only a cross section of a perfect circle but also an elliptical cross section.

Here, the wiring material 8 including the curved portion CP2 in the second portion P2 can be prepared, for example, by various processes before joining to the solar cell element 2. For example, for the wiring material 8 having a circular cross section, for example, the wiring material 8 including the curved portion CP2 in the second portion P2 can be easily realized by a simple bending process.

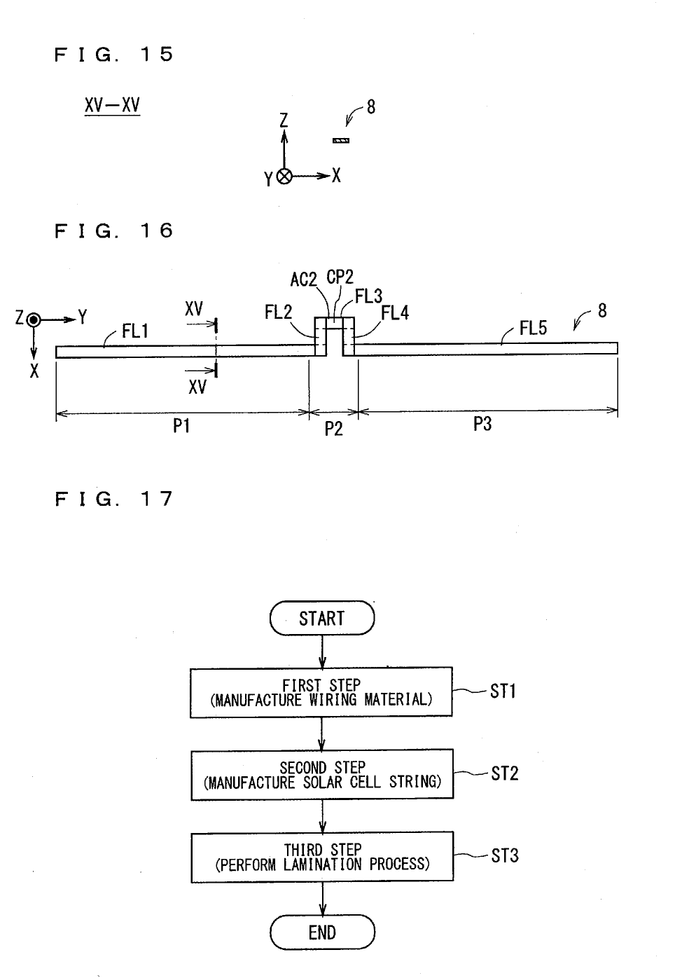

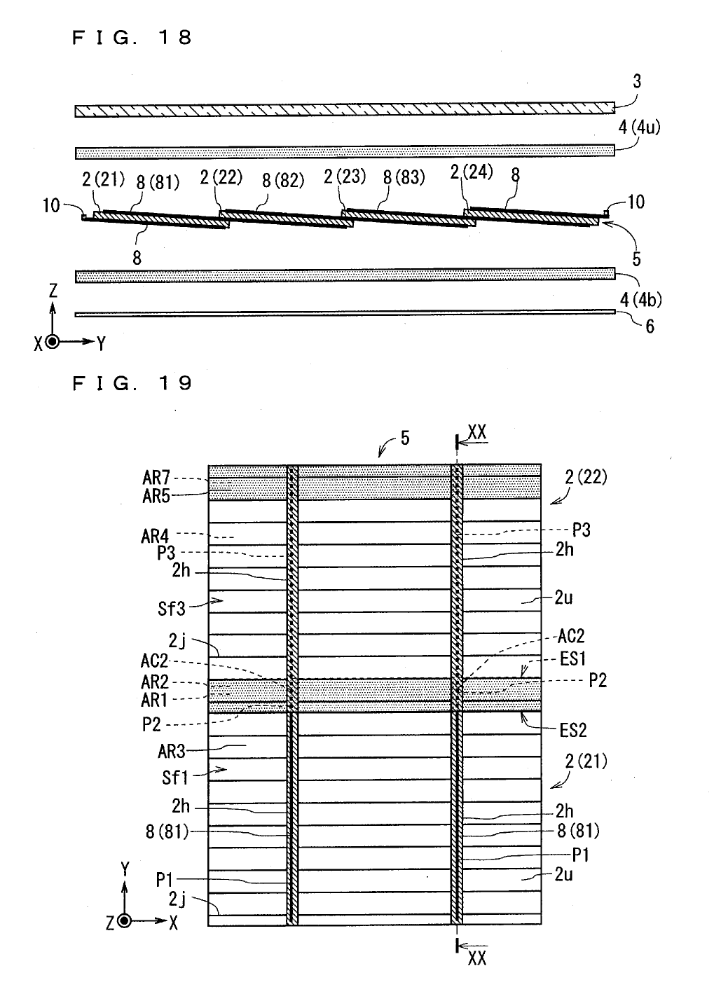

As shown in FIGS. 14 and 15, for example, a wiring material 8 having a rectangular cross section cut along a plane orthogonal to the longitudinal direction may also be adopted. That is, the shape of the wiring material 8 may be in a band shape. Here, for example, the wiring material 8 including the curved portion CP2 can be manufactured by applying a process called such as roll forming or incremental bending to a conductive metal band. Further, for example, a wiring material 8 including a curved portion CP2 may be manufactured by applying a punching process to a conductive metal plate or sheet. Further, as shown in FIG. 16, for example, one band-shaped wiring material 8 including the curved portion CP2 may be realized by connecting a plurality of band-shaped portions FL1, FL2, FL3, FL4, and FL5.

Further, in the examples of FIGS. 7 to 9, the second solar cell element 22 has, for example, an end surface (also referred to as a third end surface) ES3 adjacent to the third solar cell element 23 and facing the first direction (+Y direction, in this case) in a state of connecting the third surface Sf3 and the fourth surface Sf4.

The third solar cell element 23 has a fifth surface Sf5, which is the element front surface 2u, and a sixth surface Sf6, which is the element rear surface 2b located on a rear side of the fifth surface Sf5. Further, for example, the third solar cell element 23 has an end face (also referred to as a fourth end surface) ES4 adjacent to the second solar cell element 22 and facing the second direction (−Y direction, in this case) in a state of connecting the fifth surface Sf5 and the sixth surface Sf6. In the first embodiment, the third solar cell element 23 has four end surfaces connecting the fifth surface Sf5 and the sixth surface Sf6. The four end surfaces include, for example, a pair of end surfaces located in a state of extending along the first direction (+Y direction, in this case), and a pair of end surfaces located in a state of extending along the +X direction orthogonal to the first direction. More specifically, in the third solar cell element 23, the four end surfaces include an end surface located in a state of extending along the +Y direction on the +X side, an end surface located in a state of extending along the +Y direction on the −X side, an end surface located in a state of extending along the +X direction on the +Y side, and an end surface located in a state of extending along the +X direction on the −Y side.

Between the second solar cell element 22 and the third solar cell element 23, for example, a fifth region AR5 of the second solar cell element 22 and a sixth region AR6 of the third solar cell element 23 overlap with each other with two second wiring materials 82 interposed in between. Here, the fifth region AR5 is located along the third end surface ES3 on the third surface Sf3. The sixth region AR6 is located along the fourth end surface ES4 on the sixth surface Sf6. In the first embodiment, the fifth region AR5 has a second width in the second direction (−Y direction) from the third end surface ES3, and located in a state of extending along the third end surface ES3 from an end portion of the third surface Sf3 on the −X side to an end portion of the third surface Sf3 on the +X side. Further, the sixth region AR6 has a second width in the first direction (+Y direction) from the fourth end surface ES4, and is located in a state of extending along the fourth end surface ES4 from an end portion of the sixth surface Sf6 on the −X side to an end portion of the sixth surface Sf6 on the +X side. The second width can be set to, for example, about several mm to 20 mm similarly to the first width described above.

Further, in the example of FIG. 9, the third portion P3 of the first wiring material 81 is located in a state of extending from the fourth region AR4 to a seventh region AR7 on the fourth surface Sf4 of the second solar cell element 22. The seventh region AR7 is a region located on a rear side of the fifth region AR5 in the second solar cell element 22. Adopting such a configuration allows, for example, the first wiring material 81 to be joined over a wider range of a region that is not overlapped with another solar cell element 2, in the first solar cell element 21 and the second solar cell element 22 that are adjacent to each other. Specifically, for example, the first wiring material 81 can be joined to more rear-surface-side bus bar electrodes 2i of the second solar cell element 22. As a result, power collection in the second solar cell element 22 can be performed efficiently.

For example, it is also possible to adopt an aspect in which the third portion P3 of the first wiring material 81 is joined to the fourth region AR4 on the fourth surface Sf4 of the second solar cell element 22, but is not located in a state of extending to the seventh region AR7. However, for example, if the third portion P3 of the first wiring material 81 is joined to more rear-surface-side bus bar electrodes 2i of the fourth surface Sf4 of the second solar cell element 22, power collection in the second solar cell element 22 can be performed efficiently. Further, for example, if the first portion P1 of the first wiring material 81 is joined to the front-surface-side bus bar electrode 2h on the first surface Sf1 of the first solar cell element 21 over a wider range, power collection in the first solar cell element 21 can be performed efficiently.

Similarly to the first wiring material 81, for example, if the second wiring material 82 is joined to the front-surface-side bus bar electrode 2h on the third surface Sf3 of the second solar cell element 22 over a wider range, power collection in the second solar cell element 22 can be performed efficiently. Further, for example, if the second wiring material 82 is joined to more rear-surface-side bus bar electrodes 2i on the sixth surface Sf6 of the third solar cell element 23, power collection in the third solar cell element 23 can be performed efficiently. Furthermore, for example, if the third wiring material 83 is joined to the front-surface-side bus bar electrode 2h on the fifth surface Sf5 of the third solar cell element 23 over a wider range, power collection in the third solar cell element 23 can be performed efficiently.

<1-1-4. Sheet Member>

The sheet member 6 can protect the rear-surface-side sealing material 4b. The sheet member 6 is located so as to cover the plurality of solar cell strings 5 from the rear surface (non-light receiving surface) 1b side on the −Z side of the solar cell module 1. Specifically, the sheet member 6 is located so as to cover the plurality of solar cell strings 5 from the element rear surface 2b side via the rear-surface-side sealing material 4b. The sheet member 6 is, for example, thinner than the light transmissive substrate 3 and has an elastic coefficient smaller than that of the light transmissive substrate 3. As a material of the sheet member 6, for example, polyvinyl fluoride (PVF), polyethylene terephthalate (PET), polyethylene naphthalate (PEN), a soft resin sheet in which two or more of these are laminated, or the like can be adopted.

<1-2. Manufacture of Solar Cell Module>

Next, an example of a manufacturing method of the solar cell module 1 will be described.

For example, as shown in FIG. 17, the solar cell module 1 can be manufactured by sequentially executing a first step ST1, a second step ST2, and a third step ST3.

For example, in the first step ST1, the wiring material 8 is manufactured. Here, for example, the wiring material 8 (FIGS. 10 and 11) can be manufactured by applying cutting at a desired pitch, a bending process, and coating of solder, to a linear metal wire.

In the second step ST2, the solar cell string 5 is manufactured. Here, for example, as shown in FIG. 18, the solar cell string 5 can be manufactured by sequentially soldering the wiring material 8 to the front and rear surfaces from the first solar cell element 21 to the fourth solar cell element 24. At this time, joining of the wiring material 8 to each solar cell element 2 by soldering can be realized, for example, by sliding one heated soldering iron on the wiring material 8 located on an object to be joined. Further, joining by soldering of the wiring material 8 to each solar cell element 2 may be realized, for example, by pressing the wiring material 8 with a plurality of heated soldering irons located at regular intervals.

In the third step ST3, as shown in FIG. 18, the light transmissive substrate 3, the front-surface-side sealing material 4u, the plurality of solar cell strings 5, the rear-surface-side sealing material 4b, and the sheet member 6 are stacked in the order described herein. Then, the light transmissive substrate 3, the front-surface-side sealing material 4u, the plurality of solar cell strings 5, the rear-surface-side sealing material 4b, and the sheet member 6 are integrated by a lamination step or the like with a laminating device (laminator). This allows the solar cell module 1 shown in FIG. 3 to be manufactured.

<1-3. Summary of First Embodiment>

In the solar cell module 1 according to the first embodiment, for example, adjacent solar cell elements 2 partially overlap with each other. Adopting such a configuration can increase, for example, a ratio of an area occupied by a power generation region where power generation is effectively performed in the solar cell element 2 to an area of the entire region of the light receiving surface 1u. This can improve, for example, conversion efficiency indicating a ratio of energy to be converted into electric energy, to optical energy of light incident on the solar cell module 1. Further, for example, electrically connecting the wiring material 8 to a non-overlapping region of adjacent solar cell elements 2 increases a cross-sectional area of the conductor through which charges collected on the element front surface 2u and the element rear surface 2b of the solar cell element 2 pass. This can facilitate extraction of charges in the solar cell element 2. As a result, for example, the output of the solar cell module 1 can be enhanced.

Then, in the solar cell module 1 according to the first embodiment, for example, in an overlapping portion of adjacent solar cell elements 2, the wiring material 8 includes the non-joined portion AC2 located in a state of not being joined to any of the solar cell elements 2 and of extending along a direction intersecting the first direction (+Y direction). Adopting such a configuration allows, for example, deformation of the wiring material 8 at the non-joined portion AC2 according to thermal expansion and thermal contraction of the solar cell element 2, the wiring material 8, and the like. Thus, even if the solar cell element 2, the wiring material 8, and the like are thermally expanded and thermally contracted in accordance with a change in temperature, for example, concentration of shear stress is unlikely to occur at a portion where the solar cell element 2 and the wiring material 8 are joined. This makes it difficult to cause, for example, occurrence of a crack in the wiring material 8 and the solar cell element 2, peeling of the front-surface-side bus bar electrode 2h and the rear-surface-side bus bar electrode 2i joined with the wiring material 8, and the like. That is, conversion efficiency and reliability of the solar cell module 1 can be enhanced.

That is, herein, for example, by appropriately adjusting a shape of the wiring material 8 and a region where the wiring material 8 is electrically connected to the solar cell element 2, conversion efficiency and reliability in the solar cell module 1 can be easily enhanced.

### 2. Other Embodiments

The present disclosure is not limited to the first embodiment, and various modifications and improvements are possible without departing from the subject matter of the present disclosure.

### 2-1. Second Embodiment

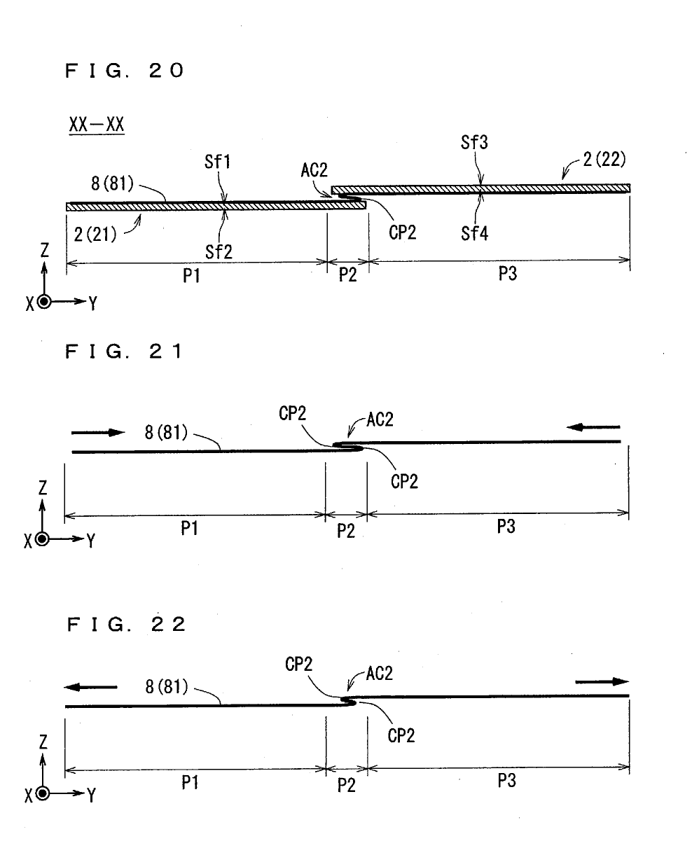

In the solar cell module 1 according to the first embodiment, for example, as shown in FIGS. 19 and 20, the non-joined portion AC2 may be configured to include the curved portion CP2 curved on a surface (also referred to as an intersecting surface) intersecting the first surface Sf1 and the fourth surface Sf4. In the example of FIGS. 19 and 20, the intersecting surface is a virtual plane perpendicular to both the first surface Sf1 and the fourth surface Sf4 and extending along the first direction (+Y direction).

Even in adopting such a configuration, for example, as shown in FIGS. 21 and 22, in accordance with thermal expansion and thermal contraction of the solar cell element 2, the wiring material 8, and the like, the wiring material 8 can be deformed at the non-joined portion AC2. Thus, even if the solar cell element 2, the wiring material 8, and the like are thermally expanded and thermally contracted in accordance with a change in temperature, for example, concentration of shear stress is unlikely to occur at a portion where the solar cell element 2 and the wiring material 8 are joined. Therefore, similarly to the first embodiment, conversion efficiency and reliability in the solar cell module 1 can be enhanced.

The wiring material 8 having the above-described configuration can be manufactured by, for example, a bending process or the like of a linear or belt-shaped material. For example, adopting a bending process or the like of a thin belt-shaped material allows the wiring material 8 to be easily manufactured.

### 2-2. Third Embodiment

In the first embodiment and the second embodiment, in plane perspective view of the solar cell module 1 from the −Z side and the +Z side, the first portion P1 and the third portion P3 of each wiring material 8 are located in a state of extending in a straight line, but the present disclosure is not limited to this.

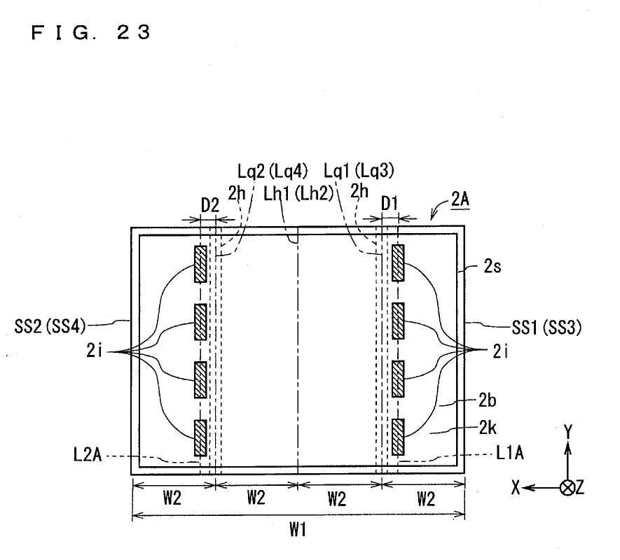

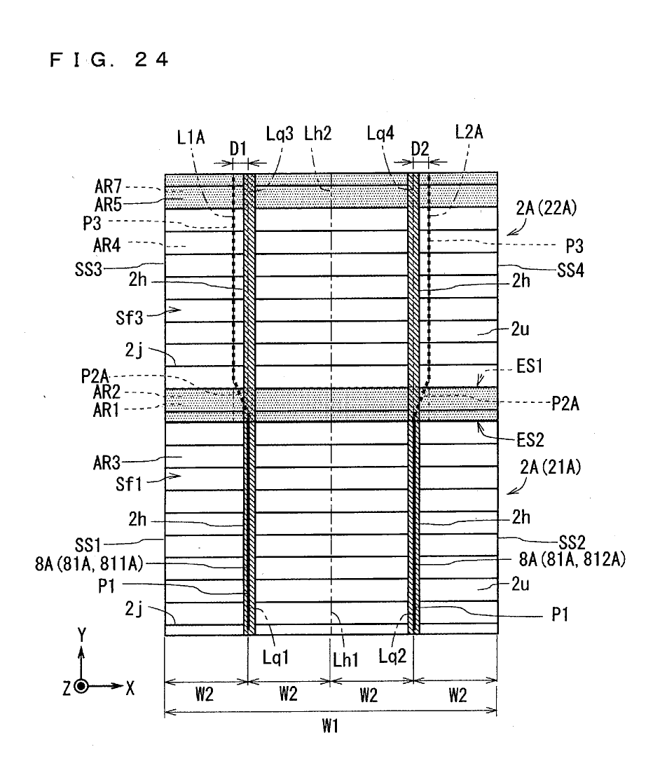

For example, as shown in FIG. 23, the solar cell element 2 according to the first embodiment may be changed to a solar cell element 2A. The solar cell element 2A has a configuration in which, with the solar cell element 2 as a base, in plane perspective view of the solar cell element 2A from the −Z side and the +Z side, a position of a rear-surface-side bus bar electrode 2i is shifted from a region on a rear side of a front-surface-side bus bar electrode 2h with a semiconductor substrate 2s interposed in between. In this case, for example, as shown in FIGS. 24 to 26, the wiring material 8 according to the first embodiment is changed to a wiring material 8A. The wiring material 8A has a configuration obtained, with the wiring material 8 as a base, by changing a form in which the wiring material 8 is located in a state of extending. For example, in the wiring material 8A, the second portion P2 of the wiring material 8 according to the first embodiment is changed to a second portion P2A having a different shape. In the wiring material 8A, a first portion P1 is located along a straight line extending in a first direction (+Y direction), a third portion P3 is located to be shifted from the straight line, and the second portion P2A includes a portion (also referred to as an intersection portion) SP2 located in a state of extending in a direction intersecting the first direction. By the above modification, for example, the first solar cell element 21 and the second solar cell element 22 are changed to a first solar cell element 21A and a second solar cell element 22A, and the first wiring material 81 is changed to a first wiring material 81A.

In the examples of FIGS. 23 to 26, the first solar cell element 21A has a first side surface SS1 and a second side surface SS2. The first side surface SS1 is located along the first direction (+Y direction) in a state of connecting the first surface Sf1 and the second surface Sf2. The second side surface SS2 is located on a rear side of the first side surface SS1 in a state of connecting the first surface Sf1 and the second surface Sf2. Further, the second solar cell element 22A has a third side surface SS3 and a fourth side surface SS4. The third side surface SS3 is located along the first direction (+Y direction) in a state of connecting the third surface Sf3 and the fourth surface Sf4. The fourth side surface SS4 is located on a rear side of the third side surface SS3 in a state of connecting the third surface Sf3 and the fourth surface Sf4.

More specifically, each side surface may have the following configuration, for example. The first side surface SS1 is a side surface located along the first direction on the −X side of the first solar cell element 21A. The second side surface SS2 is a side surface located along the first direction on the +X side of the first solar cell element 21A. The third side surface SS3 is a side surface located along the first direction on the −X side of the second solar cell element 22A. The fourth side surface SS4 is a side surface located along the first direction on the +X side of the second solar cell element 22A.

Here, in plan view of the first solar cell element 21A from the first surface Sf1 side or the second surface Sf1 side, a virtual line located intermediate between the first side surface SS1 and the second side surface SS2 is defined as a first intermediate line Lh1. Further, a virtual line located intermediate between the first intermediate line Lh1 and the first side surface SS1 is defined as a first quarter-line Lq1. Furthermore, a virtual line located intermediate between the first intermediate line Lh1 and the second side surface SS2 is defined as a second quarter-line Lq2. More specifically, for example, the following virtual condition is set. A width in the +X direction of the first solar cell element 21A is defined as a width W1, and a distance obtained by dividing the width W1 by 4 is defined as a distance W2. In this case, the first side surface SS1 and the first quarter-line Lq1 are parallel and are separated by the distance W2. Further, the second side surface SS2 and the second quarter-line Lq2 are parallel and are separated by the distance W2.

In the examples of FIGS. 23 to 26, two first wiring materials 81A include a first first-wiring-material 811A and a second first-wiring-material 812A. Then, for example, in plan view of the first solar cell element 21A from the first surface Sf1 side, the first portion P1 of the first first-wiring-material 811A is located along the first quarter-line Lq1. Here, for example, the first portion P1 of the first first-wiring-material 811A may be located so as to overlap with the first quarter-line Lq1. Further, the first portion P1 of the second first-wiring-material 812A is located along the second quarter-line Lq2. Here, for example, the first portion P1 of the second first-wiring-material 812A may be located so as to overlap with the second quarter-line Lq2. Here, if the first surface Sf1 is equally divided into two regions at a position of the first intermediate line Lh1, the first portion P1 of the first first-wiring-material 811A is located at a center in a width direction (+X direction) of a region on the −X side of the first surface Sf1. Further, the first portion P1 of the second first-wiring-material 812A is located at a center in the width direction (+X direction) of a region on the +X side of the first surface Sf1. Therefore, for example, in the first solar cell element 21A, uniform power collection can be performed without unevenness, by the two wiring materials 8A on the first surface Sf1.

Here, for example, in plan view of the second solar cell element 22A from the third surface Sf3 or the fourth surface Sf4 side, a virtual line located intermediate between the third side surface SS3 and the fourth side surface SS4 is defined as a second intermediate line Lh2. Further, for example, a virtual line located intermediate between the second intermediate line Lh2 and the third side surface SS3 is defined as a third quarter-line Lq3. Furthermore, for example, a virtual line located intermediate between the second intermediate line Lh2 and the fourth side surface SS4 is defined as a fourth quarter-line Lq4. More specifically, for example, the following virtual condition is set. A width in the +X direction of the second solar cell element 22A is defined as a width W1, and a distance obtained by dividing the width W1 by 4 is defined as a distance W2. In this case, the third side surface SS3 and the third quarter-line Lq3 are parallel and are separated by the distance W2. Further, the fourth side surface SS4 and the fourth quarter-line Lq4 are parallel and separated by the distance W2. Further, in this case, in the examples of FIGS. 23 to 26, the first quarter-line Lq1 and the third quarter-line Lq3 are located on a straight line, and the second quarter-line Lq2 and the fourth quarter-line Lq4 are located on a straight line.

In the examples of FIGS. 23 to 26, in plan view of the second solar cell element 22A from the fourth surface Sf4 side, the third portion P3 of the first first-wiring-material 811A is located along a virtual first A virtual line L1A located to be shifted by a distance D1 from the third quarter-line Lq3 toward the third side surface SS3. Here, for example, the third portion P3 of the first first-wiring-material 811A may be located to overlap with the first A virtual line L1A. In addition, for example, the third portion P3 of the second first-wiring-material 812A is located along a second A virtual line L2A located to be shifted by a distance D2 from the fourth quarter-line Lq4 toward the fourth side surface SS4. Here, for example, the third portion P3 of the second first-wiring-material 812A may be located to overlap with the second A virtual line L2A. In this case, for example, the rear-surface-side bus bar electrode 2i on the −X side (also referred to as a rear-surface-side bus bar electrode of a first row) is located along the first A virtual line L1A. Here, for example, the rear-surface-side bus bar electrode 2i of the first row may be located so that a center line virtually connecting centers in a short direction of the rear-surface-side bus bar electrode 2i of the first row corresponds to the first A virtual line L1A. Further, for example, the rear-surface-side bus bar electrode 2i on the +X side (also referred to as a rear-surface-side bus bar electrode of a second row) is located along the second A virtual line L2A. Here, for example, the rear-surface-side bus bar electrode 2i of the second row may be located so that a center line virtually connecting centers in a short direction of the rear-surface-side bus bar electrode 2i of the second row corresponds to the second A virtual line L2A. The distance D1 and the distance D2 may be the same or different.

Here, for example, in the second solar cell element 22A, a collector electrode 2k having conductivity is located over a wide range of the element rear surface 2b. Therefore, in the second solar cell element 22A, for example, even if a position of the rear-surface-side bus bar electrode 2i is shifted from the third and fourth quarter-lines Lq3 and Lq4, power collection efficiency on the fourth surface Sf4 is unlikely to decrease. Therefore, in each solar cell element 2A, power collection in the solar cell element 2A can be performed efficiently if uniform power collection is performed without unevenness, by the two wiring materials 8A on the element front surface 2u.

In the examples of FIGS. 23 to 26, the first portion P1 and the third portion P3 of one first wiring material 81A are not located on a straight line, and the non-joined portion AC2 of the second portion P2A includes a first one of curved portions (also referred to as a first curved portion) CP21, an intersection portion SP2, and a second one of curved portions (also referred to as a second curved portion) CP22. The first curved portion CP21, the intersection portion SP2, and the second curved portion CP22 are connected in the order described herein. For example, the first curved portion CP21 connects the first portion P1 and the intersection portion SP2. For example, the second curved portion CP22 connects the intersection portion SP2 and the third portion P3. Adopting such a configuration allows, for example, deformation of the wiring material 8A at the non-joined portion AC2 according to thermal expansion and thermal contraction of the solar cell element 2A, the wiring material 8A, and the like. Thus, even if the solar cell element 2A, the wiring material 8A, and the like are thermally expanded and thermally contracted in accordance with a change in temperature, for example, concentration of shear stress is unlikely to occur at a portion where the solar cell element 2A and the wiring material 8A are joined. Therefore, similarly to each of the above embodiments, conversion efficiency and reliability in the solar cell module 1 can be enhanced.

Meanwhile, in the first embodiment, as shown in FIG. 10, for example, the first portion P1 and the third portion P3 are located on a straight line in the wiring material 81. Then, for example, the second portion P2 includes a portion located in a state of extending in a direction away from the straight line and a portion located in a state of extending in a direction returning onto the straight line. On the other hand, in the third embodiment, for example, the first portion P1 and the third portion P3 are not located on a straight line. Then, for example, the second portion P2A includes the intersection portion SP2 located in a state of extending in a direction away from the straight line. Therefore, for example, if the first portion P1 and the third portion P3 of one wiring material 8A are not located on a straight line, it is possible to achieve simplification of a shape of the second portion P2A connecting the first portion P1 and the third portion P3. In this case, for example, an amount of a material used for manufacturing the wiring material 8A can be reduced by reducing a length of the second portion P2A. That is, for example, it is possible to easily manufacture the wiring material 8A.

Therefore, in the third embodiment, for example, it is possible to easily manufacture the wiring material 8A, and to enhance conversion efficiency and reliability in the solar cell module 1.

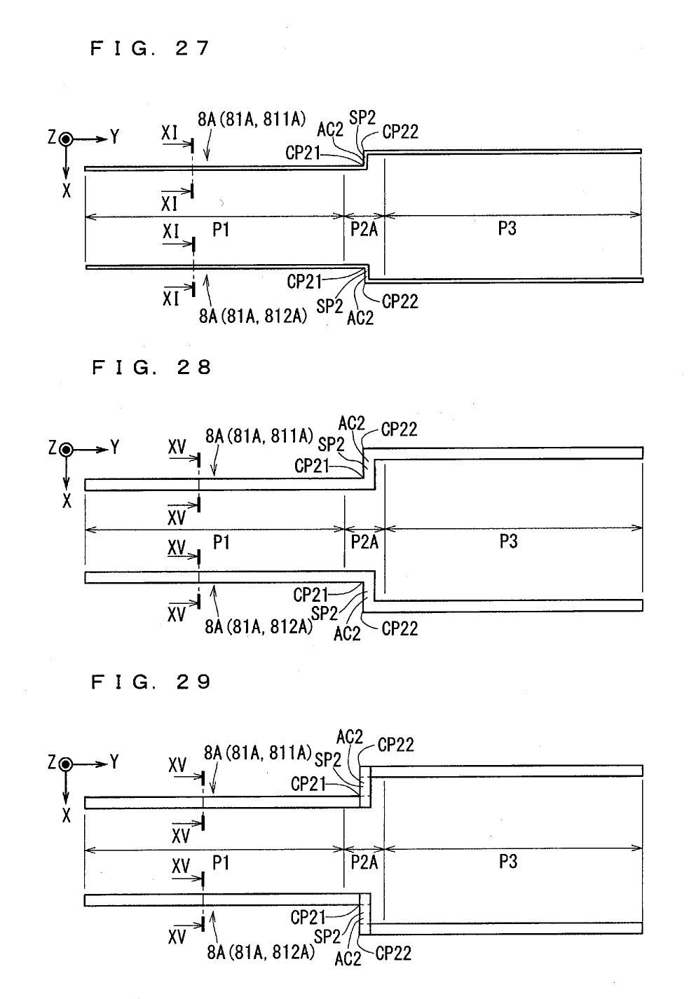

For example, as shown in FIG. 26, the intersection portion SP2 may intersect so as to form an angle of less than 90 degrees with respect to a virtual line along the first direction (+Y direction), or may be orthogonal to the virtual line along the first direction (+Y direction) as shown in FIG. 27. For example, the intersection portion SP2 may be formed so as to form any angle with respect to the virtual line along the first direction (+Y direction). Further, as shown in FIGS. 28 and 29, for example, a wiring material 8A having a rectangular cross section cut along a plane orthogonal to the longitudinal direction of the wire material 8A may also be adopted. That is, the shape of the wiring material 8A may be in a band shape. Here, for example, the wiring material 8A including the first and second curved portions CP21 and CP22 can be manufactured by applying a process called such as roll forming or incremental bending to a conductive metal band. Further, for example, the wiring material 8A including the first and second curved portions CP21 and CP22 may be manufactured by applying a punching process to a conductive metal plate or sheet. Further, as shown in FIG. 29, for example, one band-shaped wiring material 8A including the first and second curved portions CP21 and CP22 may be manufactured by connecting a plurality of band-shaped portions.

### 2-3. Fourth Embodiment

In the third embodiment, for example, in plan view of the first solar cell element 21A from the first surface Sf1 side, the first portion P1 of the first first-wiring-material 811A is located along the first quarter-line Lq1, and the first portion P1 of the second first-wiring-material 812A is located along the second quarter-line Lq2, but the present disclosure is not limited to this. For example, the first portion P1 of the first first-wiring-material 811A may be located to be shifted from the first quarter-line Lq1, and the first portion P1 of the second first-wiring-material 812A may be located to be shifted from the second quarter-line Lq2.

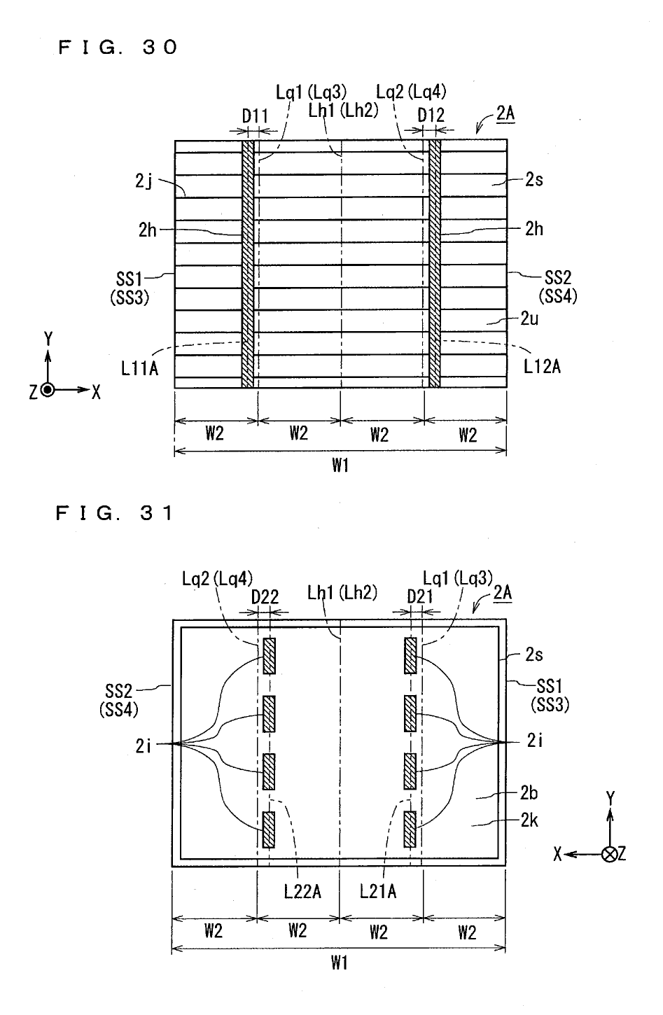

In the examples shown in FIGS. 30 and 31, in plane perspective view from the −Z side and +Z side, a first solar cell element 21A has a configuration in which a front-surface-side bus bar electrode 2h and a rear-surface-side bus bar electrode 2i located with a semiconductor substrate 2s interposed in between are in a state of being shifted in opposite directions from each other. Here, for example, in a direction opposite to a direction in which the rear-surface-side bus bar electrode 2i is shifted from a third quarter-line Lq3, the front-surface-side bus bar electrode 2h is located in a state of being shifted from a first quarter-line Lq1. Further, for example, in a direction opposite to a direction in which the rear-surface-side bus bar electrode 2i is shifted from a fourth quarter-line Lq4, the front-surface-side bus bar electrode 2h is located in a state of being shifted from a second quarter-line Lq2. Specifically, a front-surface-side bus bar electrode 2h on the −X side (also referred to as a first front-surface-side bus bar electrode) is located in a state of being shifted by a distance D11 from the first quarter-line Lq1 toward a first side surface SS1. Further, a front-surface-side bus bar electrode 2h on the +X side (also referred to as a second front-surface-side bus bar electrode) is located in a state of being shifted by a distance D12 from the second quarter-line Lq2 toward a second side surface SS2. Further, a rear-surface-side bus bar electrode 2i on the −X side (rear-surface-side bus bar electrode of a first row) is located in a state of being shifted by a distance D21 from the third quarter-line Lq3 toward a third side surface SS3. Further, a rear-surface-side bus bar electrode 2i on the +X side (rear-surface-side bus bar electrode of a second row) is located in a state of being shifted by a distance D22 from the fourth quarter-line Lq4 toward a fourth side surface SS4.

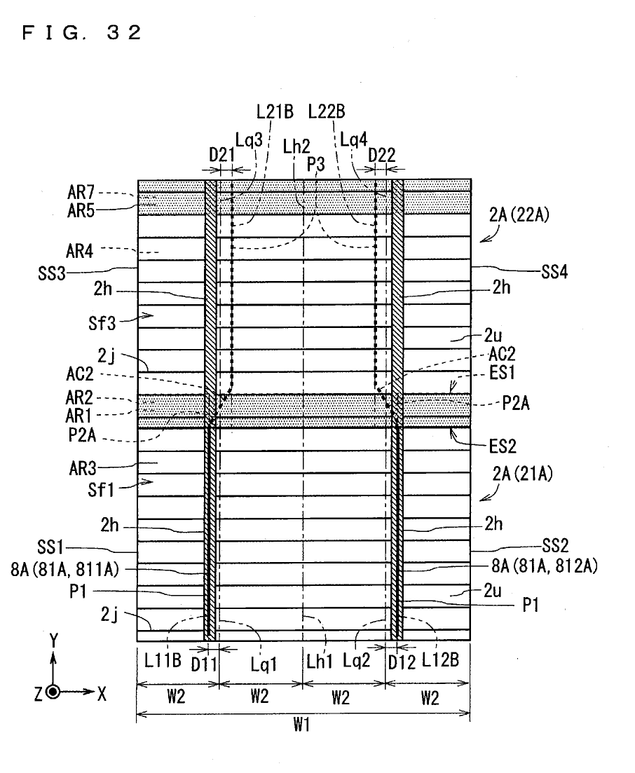

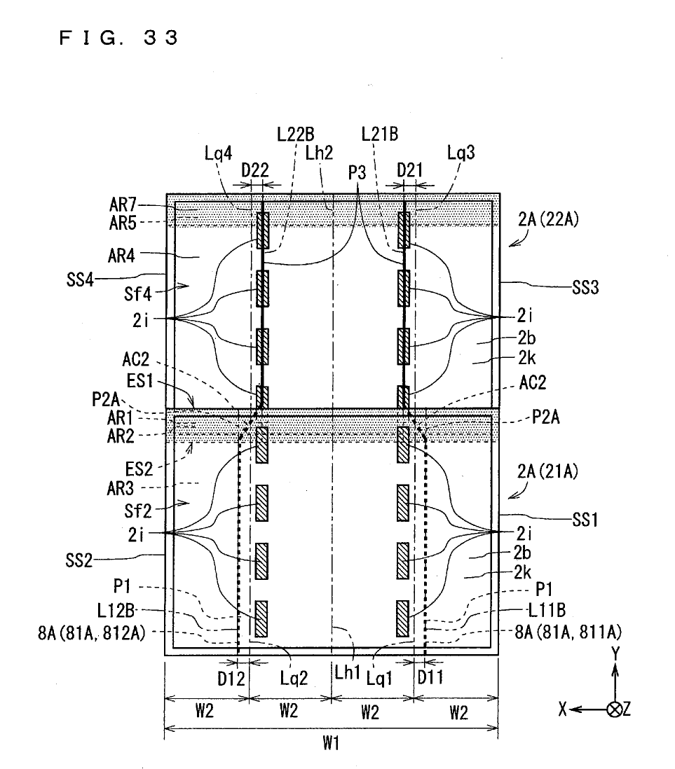

In the examples of FIGS. 32 and 33, in plan view of the first solar cell element 21A from the first surface Sf1 side, a first portion P1 of a first first-wiring-material 811A is located along a first B virtual line L11B. Here, for example, the first portion P1 of the first first-wiring-material 811A may be located so as to overlap with the first B virtual line L11B. The first B virtual line L11B is a virtual line located to be shifted by the distance D11 in a direction (also referred to as a first shift direction) from the first quarter-line Lq1 toward the first side surface SS1. Here, the first shift direction is the −X direction. Further, for example, in plan view of the first solar cell element 21A from the first surface Sf1 side, the first portion P1 of a second first-wiring-material 812A is located along a second B virtual line L12B. Here, for example, the first portion P1 of the second first-wiring-material 812A may be located so as to overlap with the second B virtual line L12B. The second B virtual line L12B is a virtual line located in a state of being shifted by the distance D12 in a direction (also referred to as a second shift direction) from the second quarter-line Lq2 toward the second side surface SS2. Here, the second shift direction is the +X direction. In this time, for example, the front-surface-side bus bar electrode 2h on the −X side (first front-surface-side bus bar electrode) is located along the first B virtual line L11B. Here, for example, the first front-surface-side bus bar electrode 2h may be located so that a center line virtually connecting centers in a short direction of the first front-surface-side bus bar electrode 2h corresponds to the first B virtual line L11B. Further, for example, the front-surface-side bus bar electrode 2h on the +X side (second front-surface-side bus bar electrode) is located along the second B virtual line L12B. Here, for example, the second front-surface-side bus bar electrode 2h may be located so that a center line virtually connecting centers in a short direction of the second front-surface-side bus bar electrode 2h corresponds to the second B virtual line L12B. For example, the distance D11 and the distance D12 may be the same or different.

Further, in the examples of FIGS. 32 and 33, in plan view of a second solar cell element 22A from a fourth surface Sf4 side, a third portion P3 of the first first-wiring-material 811A is located along a third B virtual line L21B. Here, for example, the third portion P3 of the first first-wiring-material 811A may be located in a state of overlapping with the third B virtual line L21B. The third B virtual line L21B is a virtual line located to be shifted by the distance D21 in a direction (also referred to as a third shift direction) opposite to the first shift direction (−X direction) with the third quarter-line Lq3 as a reference. Here, the third shift direction is the +X direction. Further, for example, in plan view of the second solar cell element 22A from the fourth surface Sf4 side, the third portion P3 of the second first-wiring-material 812A is located along a fourth B virtual line L22B. Here, for example, the third portion P3 of the second first-wiring-material 812A may be located in a state of overlapping with the fourth B virtual line L22B. The fourth B virtual line L22B is a virtual line located to be shifted by the distance D22 in a direction (also referred to as a fourth shift direction) opposite to the second shift direction (+X direction) with the fourth quarter-line Lq4 as a reference. Here, the fourth shift direction is the −X direction. In this case, for example, the rear-surface-side bus bar electrode 2i on the −X side (rear-surface-side bus bar electrode of the first row) is located along the third B virtual line L21B. Here, for example, the rear-surface-side bus bar electrode 2i of the first row may be located so that a center line virtually connecting centers in a short direction of the rear-surface-side bus bar electrode 2i of the first row corresponds to the third B virtual line L21B. Further, for example, the rear-surface-side bus bar electrode 2i on the +X side (rear-surface-side bus bar electrode of the second row) is located along the fourth B virtual line L22B. Here, for example, the rear-surface-side bus bar electrode 2i of the second row may be located so that a center line virtually connecting centers in the short direction of the rear-surface-side bus bar electrode 2i of the second row corresponds to the fourth B virtual line L22B. For example, the distance D21 and the distance D22 may be the same or different.

As described above, in the fourth embodiment, similarly to the third embodiment, for example, the first portion P1 and the third portion P3 are not located on a straight line, and for example, the second portion P2A includes the intersection portion SP2 located in a state of extending in a direction away from the straight line. Therefore, for example, it is possible to simplify a shape of the second portion P2A. At this time, for example, an amount of a material used for manufacturing the wiring material 8A can be reduced by reducing a length of the second portion P2A. That is, for example, it is possible to easily manufacture the wiring material 8A, and to enhance conversion efficiency and reliability in the solar cell module 1.

In the fourth embodiment, for example, the first surface Sf1 and the third surface Sf3 may be located on a light receiving surface 1u side, the second surface Sf2 and the fourth surface Sf4 may be located on a non-light receiving surface 1b side, and each of the first surface Sf1 to the fourth surface Sf4 may have a similar electrode configuration. For example, in the fourth surface Sf4, a plurality of finger electrodes 2j may be located instead of the collector electrode 2k, and the front-surface-side bus bar electrode 2h may have a configuration similar to that of the front-surface-side bus bar electrode 2h. In this case, if the first shift direction and the third shift direction are opposite directions, and the second shift direction and the fourth shift direction are opposite directions, then power collection efficiency by the wiring material 8A on the first surface Sf1 and power collection efficiency by the wiring material 8A on the fourth surface Sf4 can be similar. Thus, for example, power collection efficiency in the solar cell element 2A is unlikely to decrease, and the first portion P1 and the third portion P3 can be shifted from a position on a straight line. Therefore, for example, power collection efficiency in the solar cell element 2A is unlikely to decrease, and the wiring material 8A can be easily manufactured.

Furthermore, here, for example, if the distance D11 and the distance D21 are the same, power collection efficiency by the wiring material 8A on the first surface Sf1 and power collection efficiency by the wiring material 8A on the fourth surface Sf4 can be similar. Further, here, for example, if the distance D12 and the distance D22 are the same, power collection efficiency by the wiring material 8A on the first surface Sf1 and power collection efficiency by the wiring material 8A on the fourth surface Sf4 can be similar. As a result, for example, even if the first portion P1 and the third portion P3 are shifted from a position on a straight line, power collection efficiency in the solar cell element 2A is unlikely to decrease. Therefore, for example, power collection efficiency in the solar cell element 2A is unlikely to decrease, and the wiring material 8A can be easily manufactured.

### 3. Other Embodiments

For example, in the first and second embodiments, adjacent solar cell elements 2 may be electrically connected to each other by one wiring material 8, or may be electrically connected by three or more wiring materials 8. That is, it is possible to adopt a configuration in which adjacent solar cell elements 2 are electrically connected with one or more wiring materials 8. In this case, it is possible to adopt a configuration in which, for example, each solar cell element 2 includes one or more front-surface-side bus bar electrodes 2h and one or more rows of rear-surface-side bus bar electrodes 2i in accordance with the number of wiring materials 8.

In each of the above embodiments, for example, at least one of the front-surface-side bus bar electrode 2h and the rear-surface-side bus bar electrode 2i may be located along a direction slightly inclined with respect to the first direction (+Y direction).

In each of the above embodiments, for example, at least one of the first portion P1 and the third portion P3 of the wiring materials 8 and 8A may be located along a direction slightly inclined with respect to the first direction (+Y direction).

In each of the above embodiments, for example, the front-surface-side bus bar electrode 2h may be omitted on the element front surface 2u, and the wiring materials 8 and 8A may be electrically connected to the plurality of finger electrodes 2j. Further, for example, the rear-surface-side bus bar electrode 2i may be omitted on the element rear surface 2b, and the wiring materials 8 and 8A may be electrically connected to the collector electrode 2k. Furthermore, for example, in a state where the plurality of finger electrodes 2j are located instead of the rear-surface-side bus bar electrode 2i and the collector electrode 2k on the element rear surface 2b, the wiring materials 8 and 8A may be electrically connected to the plurality of finger electrodes 2j.

In each of the above embodiments, for example, on the element front surface 2u side of the semiconductor substrate 2s, a transparent electrode layer may be located instead of the plurality of finger electrodes 2j. As the transparent electrode layer, for example, a tin-doped indium oxide (ITO) layer can be adopted. In this case, for example, it is possible to solder the wiring materials 8 and 8A onto the transparent electrode by ultrasonic soldering.

In each of the above embodiments, for example, the solar cell string 5 may include two or more solar cell elements 2 and 2A.

In each of the above embodiments, for example, the solar cell module 1 may include one or more solar cell strings 5.

In each of the above embodiments, for example, the non-joined portion AC2 may protrude from a portion where two adjacent solar cell elements 2 and 2A overlap with each other or may not protrude therefrom. From another viewpoint, for example, the second portions P2 and P2A may protrude from a portion where two adjacent solar cell elements 2 and 2A overlap with each other or may not protrude therefrom. From even another viewpoint, for example, at least one of the first portion P1 or the third portion P3 may enter a portion where two adjacent solar cell elements 2 and 2A overlap each other.

In the third embodiment, for example, the first A virtual line L1A may be shifted by the distance D1 from the third quarter-line Lq3 toward the fourth side surface SS4, and the second A virtual line L2A may be shifted by the distance D2 from the fourth quarter-line Lq4 toward the third side surface SS3.

In the fourth embodiment, for example, the first B virtual line L11B may be shifted by the distance D11 from the first quarter-line Lq1 toward the second side surface SS2, and the third B virtual line L21B may be shifted by the distance D21 from the third quarter-line Lq3 toward the third side surface SS3. Further, for example, the second B virtual line L12B may be shifted by the distance D12 from the second quarter-line Lq2 toward the first side surface SS1, and the fourth B virtual line L22B may be shifted by the distance D22 from the fourth quarter-line Lq4 toward the fourth side surface SS4.

In the third embodiment and the fourth embodiment, for example, the first and second curved portions CP21 and CP22 in the wiring material 8A may protrude from a portion where the adjacent two solar cell elements 2 and 2A overlap with each other or may not protrude therefrom. In other words, for example, the first and second curved portions CP21 and CP22 of the wiring material 8A may be located in a region between the first region AR1 and the second region AR2, or may be located outside the region between the first region AR1 and the second region AR2. That is, for example, at least one of the first curved portion CP21 and the second curved portion CP22 of the wiring material 8A may be located in the region between the first region AR1 and the second region AR2, or may be located outside the region between the first region AR1 and the second region AR2.

In the third embodiment and the fourth embodiment, for example, the non-joined portion AC2 may not include the first curved portion CP21 and the second curved portion CP22. That is, for example, as long as the non-joined portion AC2 includes the intersection portion SP2, the wiring material 8A can be deformed in accordance with thermal expansion of the solar cell element 2A, the wiring material 8A, or the like at the intersection portion SP2. Therefore, for example, as long as the non-joined portion AC2 includes the intersection portion SP2 located so as to intersect a virtual line along the first direction (+Y direction), conversion efficiency and reliability in the solar cell module 1 can be enhanced. Then, as long as the non-joined portion AC2 includes at least one of the first curved portion CP21 and the second curved portion CP22, the wiring material 8A can be easily deformed in accordance with thermal expansion and thermal contraction of the solar cell element 2A, the wiring material 8A, or the like at the curved portion.

In each of the above embodiments, for example, the wiring material 8 may be joined to the solar cell elements 2 and 2A by a method other than soldering. As the method other than soldering, for example, a method using applying, drying, baking, and the like of a conductive metal paste, and a method of bonding with a conductive adhesive can be considered.

All or part constituting each of the first to fourth embodiments and other embodiments can be appropriately combined in a range not inconsistent.

1. A solar cell module comprising:
a plurality of solar cell elements including a first solar cell element having a first surface and a second surface opposite the first surface; and a second solar cell element having a third surface and a fourth surface opposite the third surface, the plurality of solar cell elements being located in a state of being arranged along a first direction; and
one or more first wiring materials located in a state of electrically connecting the first surface and the fourth surface,
wherein the first solar cell element has a first end surface adjacent to the second solar cell element and facing the first direction in a state of connecting the first surface and the second surface,
the second solar cell element has a second end surface adjacent to the first solar cell element and facing a second direction opposite to the first direction, in a state of connecting the third surface and the fourth surface,
a first region located along the first end surface on the first surface and a second region located along the second end surface on the fourth surface are located in a state of overlapping with each other with the one or more first wiring materials interposed in between,
each of the one or more first wiring materials includes a first portion, a second portion, and a third portion sequentially located along a longitudinal direction of a corresponding one of the one or more first wiring materials,
the first portion is in a state of being joined to a third region different from the first region on the first surface,
the third portion is in a state of being joined to a fourth region different from the second region on the fourth surface,
the second portion includes a non-joined portion located between the first region and the second region and located in a state of not being joined to any of the first region and the second region, and
the non-joined portion is located in a state of extending along a direction intersecting the first direction.

2. The solar cell module according to claim 1, wherein the non joined portion is located along the first surface and the fourth surface.

3. The solar cell module according to claim 1, wherein the non-joined portion includes a curved portion.

4. The solar cell module according to claim 1, wherein
the plurality of solar cell elements include a third solar cell element having a fifth surface and a sixth surface opposite the fifth surface, and located at a position shifted from the second solar cell element in the first direction,
the second solar cell element has a third end surface adjacent to the third solar cell element and facing the first direction in a state of connecting the third surface and the fourth surface,
the third solar cell element has a fourth end surface adjacent to the second solar cell element and facing the second direction in a state of connecting the fifth surface and the sixth surface,
a fifth region located along the third end surface on the third surface and a sixth region located along the fourth end surface on the sixth surface are located in a state of overlapping with each other with one or more second wiring materials interposed in between, and
the third portion of the each of the one or more first wiring materials is located on the fourth surface from the fourth region to a seventh region opposite the fifth region.

5. The solar cell module according to claim 1, wherein the each of the one or more first wiring materials has a circular cross section perpendicular to a longitudinal direction of a corresponding one of the one or more first wiring materials.

6. The solar cell module according to claim 1, wherein
the first solar cell element has a first side surface located along the first direction in a state of connecting the first surface and the second surface, and a second side surface opposite the first side surface in a state of connecting the first surface and the second surface,
the second solar cell element has a third side surface located along the first direction in a state of connecting the third surface and the fourth surface, and a fourth side surface opposite the third side surface in a state of connecting the third surface and the fourth surface,
the one or more first wiring materials include a first first-wiring-material and a second first-wiring-material,
in plan view of the first solar cell element from the first surface side, the first portion of the first first-wiring-material is located along a virtual first quarter-line located intermediate between the first side surface and a virtual first intermediate line located intermediate between the first side surface and the second side surface, and the first portion of the second first-wiring-material is located along a virtual second quarter-line located intermediate between the virtual first intermediate line and the second side surface, and
in plan view of the second solar cell element from the fourth surface side, the third portion of the first first-wiring-material is located along a virtual first A virtual line located to be shifted toward the third side surface or the fourth side surface from a virtual third quarter-line located intermediate between the third side surface and a virtual second intermediate line located intermediate between the third side surface and the fourth side surface, and the third portion of the second first-wiring-material is located along a virtual second A virtual line located to be shifted toward the third side surface or the fourth side surface from a virtual fourth quarter-line located intermediate between the virtual second intermediate line and the fourth side surface.

7. The solar cell module according to claim 1, wherein
the first solar cell element has a first side surface located along the first direction in a state of connecting the first surface and the second surface, and a second side surface opposite the first side surface in a state of connecting the first surface and the second surface,
the second solar cell element has a third side surface located along the first direction in a state of connecting the third surface and the fourth surface, and a fourth side surface opposite the third side surface in a state of connecting the third surface and the fourth surface,
the one or more first wiring materials include a first first-wiring-material and a second first-wiring-material,
in plan view of the first solar cell element from the first surface side, the first portion of the first first-wiring-material is located along a virtual first B virtual line located to be shifted in a first shift direction toward the first side surface or the second side surface from a virtual first quarter-line located intermediate between the first side surface and a virtual first intermediate line located intermediate between the first side surface and the second side surface, and the first portion of the second first-wiring-material is located along a virtual second B virtual line located to be shifted in a second shift direction toward the first side surface or the second side surface from a virtual second quarter-line located intermediate between the virtual first intermediate line and the second side surface, and
in plan view of the second solar cell element from the fourth surface side, the third portion of the first first-wiring-material is located along a virtual third B virtual line located to be shifted in a third shift direction opposite to the first shift direction with a virtual third quarter-line as a reference, the virtual third quarter-line being located intermediate between the third side surface and a virtual second intermediate line located intermediate between the third side surface and the fourth side surface, and the third portion of the second first-wiring-material is located along a virtual fourth B virtual line located to be shifted in a fourth shift direction opposite to the second shift direction with a virtual fourth quarter-line as a reference, the virtual fourth quarter-line being located intermediate between the virtual second intermediate line and the fourth side surface.
